(19) United States
(12) Patent Application Publication
(10) Pub. No.: US 2019/0113581 A1
(43) Pub. Date: Apr. 18, 2019

(54) BATTERY STATE ESTIMATION METHOD AND BATTERY STATE ESTIMATION DEVICE

(71) Applicant: Honda Motor Co.,Ltd., Tokyo (JP)

(72) Inventor: Masayuki KAWAMURA, Saitama (JP)

(73) Assignee: Honda Motor Co.,Ltd., Tokyo (JP)

(21) Appl. No.: 16/158,307

(22) Filed: Oct. 12, 2018

(30) Foreign Application Priority Data
Oct. 12, 2017 (JP) 2017-198346
Oct. 26, 2017 (JP) 2017-207204

(51) Int. Cl. G01R 31/392; H02J 7/00; G01R 31/36; G01R 31/382

(52) U.S. Cl. CPC G01R 31/392; G01R 31/382; G01R 31/3648; H02J 7/0068

(57) ABSTRACT

A battery state estimation method is provided. The method includes a first charging step for charging a high-voltage battery until a full charge state is reached, a discharging step for discharging the battery from the full charge state to a lower-limit charge state and calculating a battery capacity of the battery by accumulating a discharge current during the discharging, a second charging step for recharging the battery from the lower-limit charge state to the full charge state, halting the charging for a predetermined period every time one of measuring points defined between the lower-limit charge state and the full charge state is reached, and measuring the OCV of the battery after a predetermined period has passed, and resuming the charging after the measuring is completed, and a correlation characteristic obtaining step for obtaining correlation characteristic of the battery based on SOC and the OCV measured at each measuring point.

### CROSS-REFERENCE TO RELATED APPLICATION

This application claims the priority benefits of Japan application serial no. 2017-198346, filed on Oct. 12, 2017, and serial no. 2017-207204, filed on Oct. 26, 2017. The entirety of each of the above-mentioned patent applications is hereby incorporated by reference herein and made a part of this specification.

### BACKGROUND OF THE INVENTION

### Field of the Invention

The invention relates to a battery state estimation method and a battery state estimation device, and, more specifically, to a battery state estimation method and a battery state estimation device for obtaining a correlation characteristic between the charging rate and the open-end voltage of a battery which changes due to degradation.

### Description of Related Art

The input/output performance of a secondary battery that is mounted on a hybrid electric vehicle (HEV), a plugin hybrid electric vehicle (PHEV), a battery-type electric vehicle (BEV) and the like changes according to the internal state of the secondary battery such as the charging rate, the battery capacity, the resistance and the like thereof. Therefore, it is necessary to estimate such an internal state, especially the charging rate (hereinafter, also referred to as the abbreviation “SOC (State Of Charge)”), with high precision so as to use the secondary battery in a mode suitable for the input/output performance thereof. Also, there exists a correlation characteristic between the charging rate and the open-end voltage (hereinafter, also referred to as the abbreviation “OCV (Open Circuit Voltage)”) of the secondary battery. Accordingly, when the SOC of the secondary battery is estimated in a travelling vehicle, it is often the case that the SOC is estimated by estimating the OCV of the secondary battery and inputting the estimated OCV in a SOC-OCV map in which the above-mentioned correlation characteristic are mapped.

Generally, the correlation characteristic between the SOC and the OCV of the secondary battery changes due to not only the type of the battery but also the degradation state thereof. Thus, Japanese Patent Application Laid-Open No. 2016-23970 (Patent Document 1) discloses technology that creates a number of above-mentioned SOC-OCV maps in advance, selects an appropriate one corresponding to the degradation state of the secondary battery from the SOC-OCV maps, and uses the selected SOC-OCV to estimate the charging rate of the secondary battery.

However, according to the technology of Patent Document 1, it is necessary to create a great number of SOC-OCV maps in advance so as to improve the estimation precision. Accordingly, it requires an enormous amount of processing time. When a plurality of SOC-OCV maps are used, it requires to use a large memory to store these maps.

The present disclosure provides a battery state estimation method and a battery state estimation device that are capable of obtaining the correlation characteristic between the SOC and the OCV with high precision without creating multiple maps in advance.

### SUMMARY OF THE INVENTION

A battery state estimation method of the present disclosure is a method for obtaining a correlation characteristic between a charging rate and an open-end voltage of a battery (for example, a high-voltage battery 2 described later) that changes due to degradation, and includes: a first charging step (for example, step S4 in FIG. 6 described later) for connecting a power source (for example, an external power source 95 described later) to the battery and charging the battery until a full charge state is reached; a discharging step (for example, step S6 of FIG. 6 described later) for discharging the battery from the full charge state to a lower-limit charge state and calculating a battery capacity of the battery by integrating a discharge current during the discharging; a second charging step (for example, steps S9 to S12 of FIG. 6 described later) for recharging the battery from the lower-limit charge state to the full charge state, halting the charging for a predetermined period every time one of multiple measuring points defined between the lower-limit charge state and the full charge state is reached, measuring the open-end voltage of the battery after at least the predetermined period of time has passed, and then resuming charging after the measuring is completed; and a correlation characteristic obtaining step (for example, step S13 of FIG. 6 described later) for obtaining the correlation characteristic of the battery based on the charging rate at each of the measuring points and the open-end voltage measured at each of the measuring points.

A battery state estimation device (for example, a charging system S described later) of the present disclosure obtains correlation characteristic between a charging rate and an open-end voltage of a battery (for example, the high-voltage battery 2 described later) that changes due to degradation, and includes a voltage detection unit (for example, a battery voltage sensor 62 described later) that detects voltage of the battery; a current detection unit (for example, a battery current sensor 61 described later) that detects a current of the battery; a charging and discharging unit (for example, a charging electronic control unit (ECU) 56 described later) that supplies electric power from a power source to the battery, and supplies electric power from the battery to a discharge target after the battery is charged until a full charge state is reached so as to discharge the battery until a lower-limit charge state is reached; a battery capacity calculation unit (for example, a battery ECU 60 and a battery capacity calculation part 672 described later) that calculates a battery capacity of the battery by accumulating a discharge current detected by the current detection unit while the battery is turned from the full charge state into the lower-limit charge state by the charging and discharging unit; an intermittent charging unit (for example. the charging ECU 56 described later) supplies electric power from a power source to the battery and charges the battery from the lower-limit charge state to the full charge state, and resumes the charging after temporarily halts charging for a predetermined period every time one of multiple measuring points defined between the lower-limit charge state and the full charge state is reached; an open-end voltage obtaining unit (for example, an open-end voltage obtaining part 673 of the battery ECU 60 described later) that obtains an open-end voltage of the battery detected by the voltage detection unit while the charging is temporarily halted at each of the measuring points by the intermittent charging unit, and a correlation characteristic obtaining unit (for example, a correlation obtaining unit 674 described later) that obtains the correlation characteristic of the battery based on the charge rate at each of the measuring points and the open-end voltage measured at each of the measuring points by the open-end voltage obtaining unit.

### BRIEF DESCRIPTION OF THE DRAWINGS

FIG. 1 is a diagram illustrating a configuration of a charging system having the battery state estimation device according to an embodiment of the present disclosure.

FIG. 2 is a function block diagram illustrating the configuration of a part relating the estimation of the SOC of the high-voltage battery in a control module realized in a battery ECU.

FIG. 3 is a diagram illustrating the configuration of an equivalent circuit model of the high-voltage battery that is used when estimating the OCV of the high-voltage battery.

FIG. 4 is a diagram illustrating an example of the SOC-OCV map.

FIG. 5 is a diagram illustrating the procedure of an intermittent charging process.

FIG. 6 is a flowchart illustrating the specific procedure of the battery state estimation method of the present disclosure.

### DESCRIPTION OF THE EMBODIMENTS

In one embodiment of the disclosure, the battery is mounted on a movable body (for example, a vehicle V described later), and the power source is an external power source (for example, an external power source 95 described later) that is disposed outside the movable body, and in one embodiment, the first charging step, the discharging step, the second charging step and the correlation characteristic obtaining step are performed upon connection of the external power source is established while the movable body is stopped.

In one embodiment of the disclosure, the movable body includes a bidirectional charger that is capable of performing external charging that charges the battery with electric power supplied by the external power source and external power supply that discharges from the battery to an external supply target disposed outside the moving body, and in one embodiment, charging in the first charging step and the second charging step and discharging in the discharging step are performed using the bidirectional charger.

In one embodiment of the disclosure, an obtainment determination unit that is operable by the user to select whether to newly obtain the correlation characteristic or not is mounted on the movable body, and in one embodiment, the first charging step, the discharging step, the second charging step and the correlation characteristic obtaining step are performed only if obtainment of the correlation characteristic is requested via the obtainment determination unit.

In one embodiment of the disclosure, the first charging step, the discharging step, the second charging step and the correlation characteristic obtaining step are performed on a condition that at least a predetermined use period has passed from a time started using the battery or a time of previous obtainment of the correlation characteristic.

(1) According to the battery state estimation method of the present disclosure, the battery capacity is calculated by, at first, charging the battery until the full charge state is reached (first charging step), then discharging the battery from the full charge state to the lower-limit charge state, and calculating the battery capacity of the battery by accumulating the discharge current during the discharging (discharging step). Accordingly, the present disclosure can precisely estimate the battery capacity of the battery. The present disclosure then charges the battery again from the lower-limit charge state to the full charge state and defines the multiple measuring points between the lower-limit charge state and the full charge state, and halts the charging for a predetermined period every time one of the measuring points is reached, measures the open-end voltage of the battery after the predetermined period has passed, and resumes the charging after the measuring is completed (second charging step). Accordingly, the present disclosure can prevent deterioration of the measurement precision of the open-end voltage at each of the measuring points. Also, in the present disclosure, the measuring points can be defined based on the battery capacity by performing the discharging step and estimating the battery capacity in advance, thus it is possible to suppress deterioration of the estimation precision of the charging rate at each of the measuring points. According to the present disclosure, the correlation characteristic between the open-end voltage and the charging rate of the battery is obtained based on the charging rate and the open-end voltage measured at each of the measuring points, which are obtained as described above. According to the present disclosure, as described above, the correlation characteristic changing due to degradation can be obtained with high precision. Also, in the battery state estimation method of the present disclosure, the estimation of the correlation characteristic can be finished in a state where the battery in the full charge state, which is convenient.

(2) As described above, in the battery state estimation method of the present disclosure, obtaining the correlation characteristic takes time because it requires performing charging, discharging and recharging. Therefore, the battery state estimation method of the present disclosure utilizes the period of time during which the movable body is stopped, that is, the period of time during which the user do not use the movable body, to perform the first charging step, the discharging step, the second charging step and the correlation characteristic obtaining step, and obtains the correlation characteristic. Thereby, it can prevent the convenience for the user from being impaired.

(3) In the battery state estimation method of the present disclosure, charging in the first charging step and the second charging step and discharging in the discharging step is performed using the bidirectional charger. Thereby, in the discharging step, it is possible to efficiently utilize the electric power discharged from the battery from the full charge state to the lower-limit charge state for the power network, the electric loads and the like connected to the bidirectional charger.

(4) It is not necessary to frequently update the correlation characteristic of the battery since the correlation characteristic gradually changes as degradation of the battery progresses. Also, the battery state estimation method of the present disclosure takes time because it requires performing discharging and recharging. Therefore, the battery state estimation method of the present disclosure performs the first charging step, the discharging step, the second charging step and the correlation characteristic obtaining step and obtains the correlation characteristic of the battery only if the user selects to newly obtain the correlation characteristic via the obtainment determination unit mounted on the movable body. Thereby, it is possible to prevent that the convenience for the user is impaired by newly obtaining the correlation characteristic despite of the intention of the user.

(5) As described above, it is not necessary to frequently update the correlation characteristic of the battery since the correlation characteristic gradually changes as degradation of the battery progresses. Therefore, the battery state estimation method of the present disclosure performs the first charging step, the discharging step, the second charging step and the correlation characteristic obtaining step on the condition that at least a predetermined use period has passed from the time started using the battery or the time of previous obtainment of the correlation characteristic. Thereby, it can be prevented that the convenience for the user is deteriorated by frequently obtaining the correlation characteristic more than necessary.

(6) The battery state estimation device of the present disclosure has the same effects as the battery state estimation method of (1) described above.

An embodiment of the present disclosure is described with reference to the drawings.

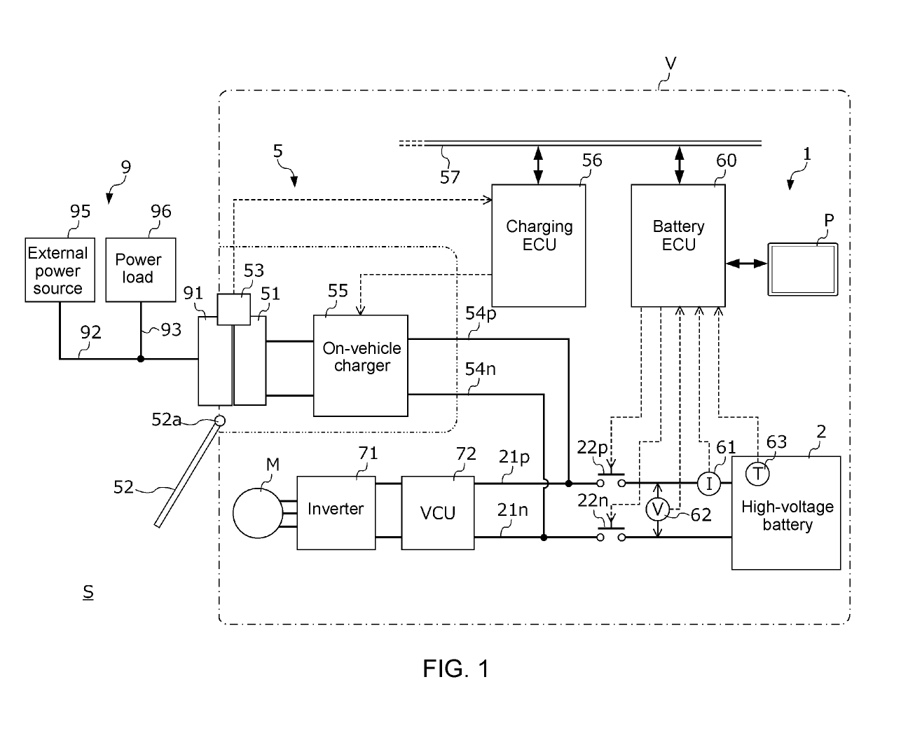

FIG. 1 is a diagram illustrating the configuration of a charging system S having the battery state estimation device according to the present disclosure. The charging system S is configured by combining an electric vehicle V (hereinafter, simply referred to as “vehicle V”) that has a high-voltage battery 2 and an inlet 51 connected to the high-voltage battery 2, and an external charger 9 that is capable of providing/receiving electric power to/from the high-voltage battery 2 of the vehicle V by connecting a connector 91 thereof to the inlet 51.

The external charger 9 is, for example, disposed in the residence of the user of the vehicle V. The external charger 9 includes a connector 91, which can be connected to the inlet 51, an external power source 95, a first feeder line 92 that connects the external power source 95 and the connector 91, a power load 96 that is disposed in the residence, and a second feeder line 93 that connects the power load 96 and the first feeder line 92.

The external power source 95 is an AC (Alternating Current) power source, and specifically a domestic AC power source that outputs AC200V, for example, but the present invention is not limited thereto. The power load 96 is a specific electronic product (e.g. a lighting or a hot-water supply) disposed in the residence, but the present invention is not limited thereto. The power load 96 only needs to be a discharge target of the high-voltage battery 2 of the vehicle V, and may be a domestic secondary battery, an electric power system and the like, other than the specific electronic products.

The user connects the external charger 9 to the vehicle V, and charge the high-voltage battery 2 of the vehicle V with the electric power supplied by the external power source 95, or connects the connector 91 to the inlet 51 when supplying the electric power supplied by the high-voltage battery 2 of the vehicle V to the power load 96. When the connector 91 is connected to the inlet 51, the first feeder line 92 and electric power lines 21p and 21n described later are electrically connected. Thereby, it becomes possible to supply electric power to the high-voltage battery 2 from the external power source 95 of the external charger 9 (hereinafter, simply referred to as “external charging”), and to supply electric power to the power load 96 from the high-voltage battery 2 (hereinafter, simply referred to as “external power supply”).

The vehicle V includes a travel motor M that is mechanically connected to a drive wheel (not depicted), a power supply system 1 that supplies electric power to the travel motor M, an inverter 71 and a voltage converter (hereinafter, referred to as the abbreviation “VCU”) 72 that convert the electric power supplied by the power supply system 1, and a touch panel P that the user can view and operate. For example, a touch panel of a car navigation system mounted on the vehicle V is used as the touch panel P.

The travel motor M is, for example, a three-phase AC motor. The VCU 72 is, for example, a bidirectional DC-DC converter having multiple switching elements (IGBT, for example). The VCU 72 boosts the direct current voltage supplied from the high-voltage battery 2 via the main electric power lines 21p and 21n described later and supplies the same to the inverter 71, or steps down the direct current voltage supplied from the inverter 71 and supplies the same to the high-voltage battery 2. The inverter 71 is, for example, a PWM (Pulse Width Modulation) inverter having a bridge circuit configured by bridging multiple switching elements (IGBT, for example). The DC input/output side of the inverter 71 is connected to the VCU 72 via main electric power lines 21p and 21n, and the AC input/output side of the inverter 71 is connected to a U phase coil, a V phase coil and a W phase coil of the travel motor M. The travel motor M generates driving force when electric power is supplied from the high-voltage battery 2 via the VCU 72 and the inverter 71 and travels. Also, the travel motor M generates electric power by regenerative operation. The electric power generated by the regenerative operation of the travel motor M is supplied to the high-voltage battery 2 via the inverter 71 and the VCU 72 and charges the high-voltage battery 2.

The power supply system 1 includes the high-voltage battery 2, a positive electrode side main power line 21p and a negative electrode side main power line 21n (hereinafter, collectively referred to as “main power lines 21p and 21n”) that connect the VCU 72 and the inverter 71 described above to the high-voltage battery 2, an external charging unit 5 to which an external charger 9 is connected, a battery ECU 60 that is an electronic control unit for estimating the internal state of the high-voltage battery 2, and sensors 61, 62 and 63 that detect the state of the high-voltage battery 2.

The high-voltage battery 2 is a secondary battery that is capable of both discharging, which converts chemical energy into electric energy, and charging, which converts electric energy into chemical energy. In the following, a case where a so-called lithium ion battery in which charging and discharging are realized by movement of lithium ions between the electrodes is used as the high-voltage battery 2 is illustrated, but the present invention is not limited thereto.

A positive electrode side main contactor 22p and a negative electrode side main contactor 22n (hereinafter, collectively referred to as “main contactors 22p and 22n”) that connect or disconnect the main power lines 21p and 21n are disposed on a side of the main power lines 21p and 21n closer to the high-voltage battery 2 than the VCU 72.

The main contactors 22p and 22n are of a normally open type that is opened to cut off the connection between the high-voltage battery 2 and the VCU 72 while no command signal from outside is being input. The main contactors 22p and 22n are opened or closed according to a command signal from the battery ECU 60. More specifically, for example, when charging/discharging is performed between the high-voltage battery 2 and the VCU 72 while the vehicle V is travelling, the main contactors 22p and 22n are closed according to a command signal from the battery ECU 60 and connect the high-voltage battery 2 and the VCU 72.

The battery current sensor 61 detects the discharge current flowing through the high-voltage battery 2 when electric power is supplied from the high-voltage battery 2 to the load such as the travel motor M or the external charger 9 and the charge current flowing through the high-voltage battery 2 when electric power is supplied from the travel motor M or the external charger 9, etc. to the high-voltage battery 2, and transmits a signal corresponding to the detected value to the battery ECU 60. The battery voltage sensor 62 detects the terminal voltage of the high-voltage battery 2, and transmits a signal corresponding to the detected value to the battery ECU 60. The battery temperature sensor 63 detects the temperature of the high-voltage battery 2, and transmits a signal corresponding to the detected value to the battery ECU 60.

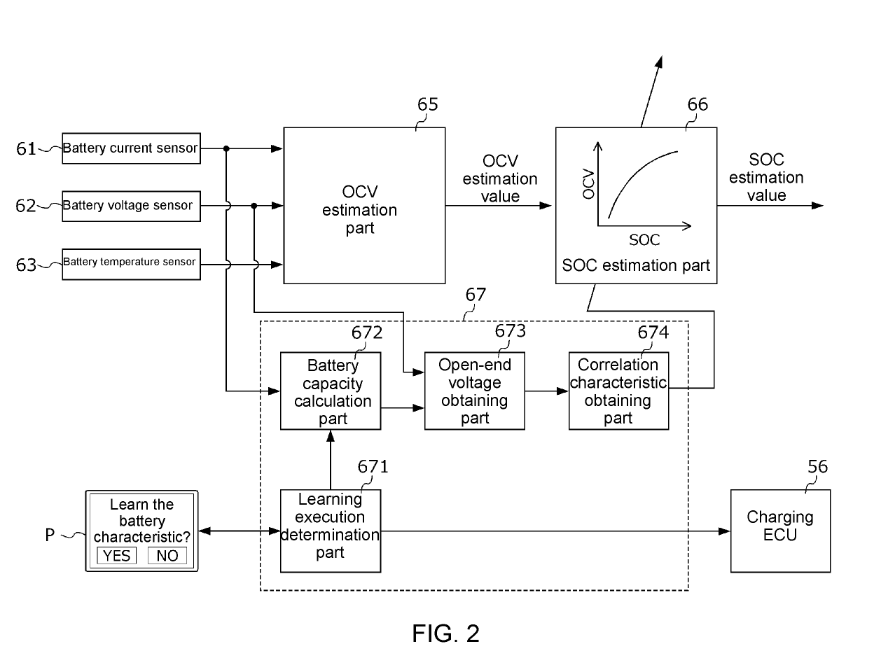

The battery ECU 60 is a microcomputer that is responsible for the control related to the estimation of the internal state of the high-voltage battery 2 (more specifically, the SOC [%] of the high-voltage battery 2), in addition to the open/close control of the main contactors 22p and 22n. Here, the SOC indicates the rate of the residual capacity over the battery capacity of the high-voltage battery 2 as a percentage. The specific method to estimate the SOC of the high-voltage battery 2 in the battery ECU 60 is described later with reference to FIG. 2.

The external charging unit 5 includes the inlet 51, which is capable of connecting the connector 91 of the external charger 9, a charge lid 52 that protects the inlet 51, a connector sensor 53 that detects the connection of the connector 91 to the inlet 51, a positive electrode side sub power line 54p and a negative electrode side sub power line 54n (hereinafter, collectively referred to as “sub power lines 54p and 54n”) that connect the inlet 51 and the main power lines 21p and 21n, an on-vehicle charger 55 that is disposed on the sub power lines 54p and 54n, and a charging ECU 56 that is an electronic control unit controlling the on-vehicle charger 55.

The sub power lines 54p and 54n extend from the inlet 51 and reach between the main contactors 22p and 22n and the VCU 72 out of the main power lines 21p and 21n. When the connector 91 is connected to the inlet 51, the first feeder line 92 of the external charger 9, the sub power lines 54p and 54n on the vehicle V side, and the main power lines 21p and 21n are electrically connected.

The charge lid 52 is of a plate shape, and is pivotally supported by a hinge 52a disposed on the body (not depicted) of the vehicle V so as to be able to open and close. The charge lid 52 constitutes a part of an outer panel of the vehicle V when the charge lid 52 is closed, and thereby the inlet 51 is protected. The inlet 51 is exposed to the outside when the charge lid 52 is opened, and thereby the user can connect the connector 91 to the inlet 51.

The connector sensor 53 is off while the connector 91 is not connected to the inlet 51. When the connector 91 is connected to the inlet 51, the connector sensor 53 transmits a signal that indicates that the connector 91 is connected to the inlet 51 to the charging ECU 56. Whether the connector 91 is connected to the inlet 51 or not is determined by the charging ECU 56 based on the detection signal from the connector sensor 53.

The on-vehicle charger 55 includes a power factor improvement circuit, a rectifying and smoothing circuit, an inverter circuit and the like. By using these circuits, the on-vehicle charger 55 can selectively perform two functions including an external charging function that charges the high-voltage battery 2 by converting AC supplied from the external power source 95 of the external charger 9 into DC and supplies the same to the high-voltage battery 2 to charge the high-voltage battery 2, and an external power supply function that converts DC supplied from the high-voltage battery 2 into AC for discharging to the power load 96 of the external charger 9, according to the control signal from the charging ECU 56.

The charging ECU 56 performs the external charging from the external power source 95 to the high-voltage battery 2 by causing the on-vehicle charger 55 to invoke the external charging function upon detecting that the connector 91 is connected to the inlet 51 via the connector sensor 53, when the SOC of the high-voltage battery 2 estimated by the battery ECU 60 is less than or equal to a predetermined value. The charging ECU 56 performs the external power supply from the high-voltage battery 2 to the power load 96 by causing the on-vehicle charger 55 to invoke the external power supply function upon detecting that the connector 91 is connected to the inlet 51 via the connector sensor 53, when the SOC of the high-voltage battery 2 estimated by the battery ECU 60 is greater than or equal to the predetermined value and the execution of the external power supply is requested by the user.

In addition, the charging ECU 56 executes a learning process (described later) that causes the on-vehicle charger 55 to invoke the external charging function and the external power supply function in a predetermined order when the execution of the learning process is requested in the battery ECU 60. The specific procedure of the learning process in the charging ECU 56 is described later in detail with reference to FIGS. 2 to 6.

The control devices such as the charging ECU 56 and the battery ECU 60 are connected to each other via a CAN bus 57 that is a bus-type network sending/receiving various control information so that necessary information can be appropriately transmitted/received among these devices.

FIG. 2 is a function block diagram illustrating the configuration of the part related to the estimation of the SOC of the high-voltage battery 2 in the control module realized in the battery ECU 60.

The battery ECU 60 includes an OCV estimation part 65 that estimates the open-end voltage (the terminal voltage of the high-voltage battery 2 when no current is flowing in the high-voltage battery 2, and, hereinafter, referred to as “OCV”) of the high-voltage battery 2 based on detection signals of the sensors 61 to 63, a SOC estimation part 66 that estimates the SOC corresponding to the OCV estimation value obtained by the OCV estimation part 65 based on the SOC-OCV map defining the correlation characteristic between the SOC and the OCV of the high-voltage battery 2, and a map learning device 67 that executes a map learning process that updates the SOC-OCV map defined in the SOC estimation part 66 according to degradation of the high-voltage battery 2.

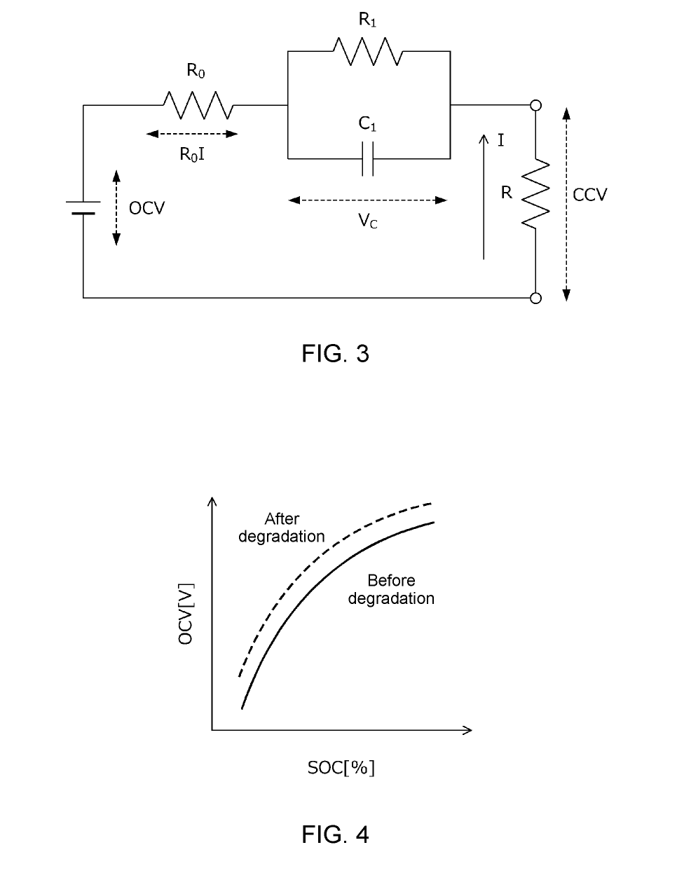

The OCV estimation part 65 calculates the OCV estimation value, which corresponds to the estimated value of the OCV of the high-voltage battery 2, based on detection signals of the sensors 61 to 63 connected to the high-voltage battery 2. For example, the OCV estimation part 65 calculates the OCV estimation value based on the equivalent circuit model of the high-voltage battery 2 that is configured by connecting in series the first internal resistor of a resistance value R₀, and a RC parallel circuit that includes a second resistor of a resistance value R₁ and an internal capacitor of a capacitance C₁ as shown in FIG. 3.

According to the equivalent circuit model of FIG. 3, the terminal voltage CCV can be represented by subtracting the first voltage drop (R₀I) at the first resistor and the second voltage drop (V_{C}) at the RC parallel circuit from the open-end voltage OVC as shown in the formula (1) described below, wherein the current flowing through the battery is I, the terminal voltage of the battery is CCV, and the open-end voltage of the battery is OCV. Also, in the formula (1) described below, the value of the terminal voltage CCV can be specified based on the detection value of the battery voltage sensor 62, the value of the current I can be specified based on the detection value of the battery current sensor 61, and the values of the resistance value R₀ and the voltage drop V_{C} can be specified based on the detection value of the battery current sensor 61 and the detection value of the battery temperature sensor 63. The OCV estimation part 65 calculates the OCV estimation value of the high-voltage battery 2 being energized, by using the detection values of the sensors 61 to 63 and the equivalent circuit model.

CCV=OCV−R₀1−V_{C} (1)

Back to FIG. 2, the SOC estimation part 66 has the SOC-OCV map (refer to FIG. 4, for example) representing the correlation characteristic between the SOC and the OCV of the high-voltage battery 2 as a map, and calculates the SOC estimation value corresponding to the OCV estimation value by inputting the OCV estimation value calculated by the OCV estimation part 65 to the SOC-OCV map. As shown in FIG. 4, the correlation characteristic between the SOC and the OCV of the high-voltage battery 2 shows nonlinear change according to the progress of degradation of the high-voltage battery 2. The contents of the SOC-OCV map defined in the SOC estimation part 66 are appropriately updated according to the progress of degradation of the high-voltage battery 2 by the learning process executed in the map learning device 67. The SOC estimation value of the high-voltage battery 2 calculated in the SOC estimation part 66 while the vehicle V is travelling is used for energy management control (not depicted) of the vehicle V, for example.

The map learning device 67 includes a learning execution determination part 671, a battery capacity calculation part 672, an open-end voltage obtaining part 673 and a correlation characteristic obtaining part 674, and executes the learning process by these.

The learning execution determination part 671 determines whether to execute the learning process or not by requesting the intention of the user via the touch panel P. Since degradation of the high-voltage battery 2 gradually progresses as the high-voltage battery 2 is used, the correlation characteristic between the SOC and the OCV of the high-voltage battery 2 also gradually changes. As described in detail later, the learning process takes several hours from the start to the completion. Therefore, it is not beneficial to frequently execute the learning process.

In the case where a predetermined use period has passed from the time started using the high-voltage battery 2 or the previous execution of the learning process, the learning execution determination part 671 displays a message on the touch panel P for asking the user whether the leaning process should be executed or not (specifically, “Learn the battery characteristic?”, for example) when the vehicle V is stopped, for example. Here, the use period is a period of time with which a significant change in the contents of the SOC-OCV map is expected to appear, and specifically is six months, for example. The learning execution determination part 671 does not request the execution of the learning process when the user operation not requesting the execution of the learning process (specifically, the operation touching the button indicating “NO”, for example) is received as a result of showing the message on the touch panel P.

The learning execution determination part 671 requests the execution of the learning process to the charging ECU 56 and the battery capacity calculation part 672 when an operation requesting the execution of the learning process from the user (specifically, the operation touching the button indicating “YES”, for example) is received as a result of showing the message on the touch panel P.

The charging ECU 56 executes the first charging process, the discharging process and the intermittent charging process in order when the execution request of the learning process is received from the learning execution determination part 671.

Firstly, in the first charging process, the charging ECU 56 charges the high-voltage battery 2 until the high-voltage battery 2 reaches a full charge state. Here, the full charge state is the state in which the SOC of the high-voltage battery 2 is 100%. Whether the high-voltage battery 2 is in the full charge state or not can be determined according to whether the voltage of the high-voltage battery 2 is greater than or equal to a predetermined upper-limit voltage or not, for example.

In the discharging process, the charging ECU 56 discharges the high-voltage battery 2 from the full charge state to the lower-limit charge state. Here, the lower-limit charge state is the state in which the SOC of the high-voltage battery 2 is 0%. Whether the high-voltage battery 2 is in the lower-limit charge state or not can be determined according to whether the voltage of the high-voltage battery 2 is greater than or equal to a predetermined lower limit voltage or not, for example.

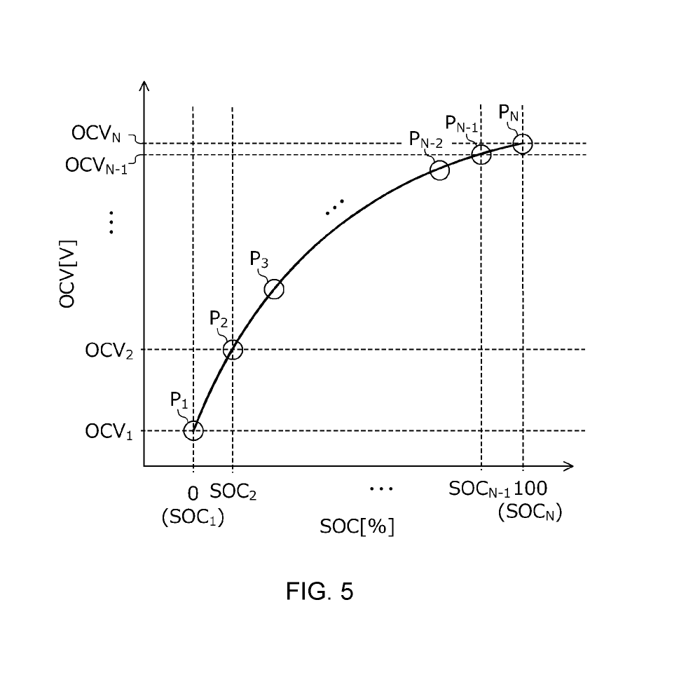

In the intermittent charging process, the charging ECU 56 intermittently charges the high-voltage battery 2 until the high-voltage battery 2 reaches the full charge state again from the lower-limit charge state. More specifically, as shown in FIG. 5, the charging ECU 56 defines three or more (N) measuring points P₁, P₂, . . . , P_{N-1} and P_{N} based on the battery capacity estimation value calculated by the battery capacity calculation part 672 described later between the lower-limit charge state indicating the SOC is 0% and the full charge state indicating the SOC is 100%. Here, the measuring point P₁ with the smallest number corresponds to the lower-limit charge state, and the measuring point P_{N} with the largest number corresponds to the full charge state. While charging from the lower-limit charge state to the full charge state, the charging ECU 56 temporarily halts the charging of the high-voltage battery 2 for a predetermined waiting period (a few minutes, for example) if the estimation value of the SOC of the high-voltage battery 2 reached SOC threshold values SOC₁ (=0), SOC₂, . . . , SOC_{N-1} and SOC_{N}(=100) defined for each of the measuring points P₁, P₂, . . . , P_{N-1} and P_{N}, and then resumes the charging after the waiting period has passed.

The position of the measuring points, that is, the magnitude of the SOC threshold value defined for the SOC at each of the measuring points may be set with a uniform interval between the lower-limit charge state to the full charge state, or may be set especially dense in a specific area in which a great change in the correlation characteristic between the SOC and the OCV is expected to appear.

Back to FIG. 2, the battery capacity calculation part 672 calculates the battery capacity estimation value, which is the estimated value of the current battery capacity of the high-voltage battery 2, by accumulating the discharge current of the high-voltage battery 2 detected by the battery current sensor 61 while the battery turns from the full charge state into the lower-limit charge state by the execution of the discharging process in the charging ECU 56.

The open-end voltage obtaining part 673 obtains the detected value of the OCV of the high-voltage battery 2 by using the battery voltage sensor 62 after the first charging process or the discharging process is executed by the charging ECU 56, or during a period in which the charging is temporarily halted for the waiting period at each of the measuring points P₁ to P_{N} as described above while the intermittent charging process is being performed in the charging ECU 56. Here, in one embodiment, the open-end voltage obtaining part 673 reads the detection value of the battery voltage sensor 62 after the waiting period or longer has passed, that is, immediately, before the charging is resumed by the charging ECU 56, instead of immediately after the charging is temporarily halted at each of the measuring points P₁ to P_{N}, to detect the OCV as precise as possible using the battery voltage sensor 62. Thereby, the open-end voltage obtaining part 673 obtains the OCV detection values OCV₁, OCV₂, . . . , OCV_{N-1}, OCV_{N} at each of the measuring points P₁, P₂, . . . , P_{N-1} and P_{N}, as shown in FIG. 5.

The correlation characteristic obtaining part 674 creates a new SOC-OCV map corresponding to the current high-voltage battery 2 based on the SOC threshold values SOC₁, SOC₂, . . . , SOC_{N-1} and SOC_{N} at each of the measuring points P₁, P₂, . . . , P_{N-1} and P_{N}, and the OCV detection values OCV₁, OCV₂, . . . , OCV_{N-1}, OCV_{N} obtained at each of the measuring points P₁, P₂, . . . , P_{N-1} and P_{N} by the open-end voltage obtaining part 673. More specifically, the correlation characteristic obtaining part 674 creates the new SOC-OCV map by generating a curved line that passes through N measuring points specified by the SOC threshold values SOC₁ to SOC_{N} and the OCV detection values OCV₁ to OCV_{N} by using a known interpolation algorism, and then replaces the SOC-OCV map defined in the SOC estimation part 66 with the newly created SOC-OCV map.

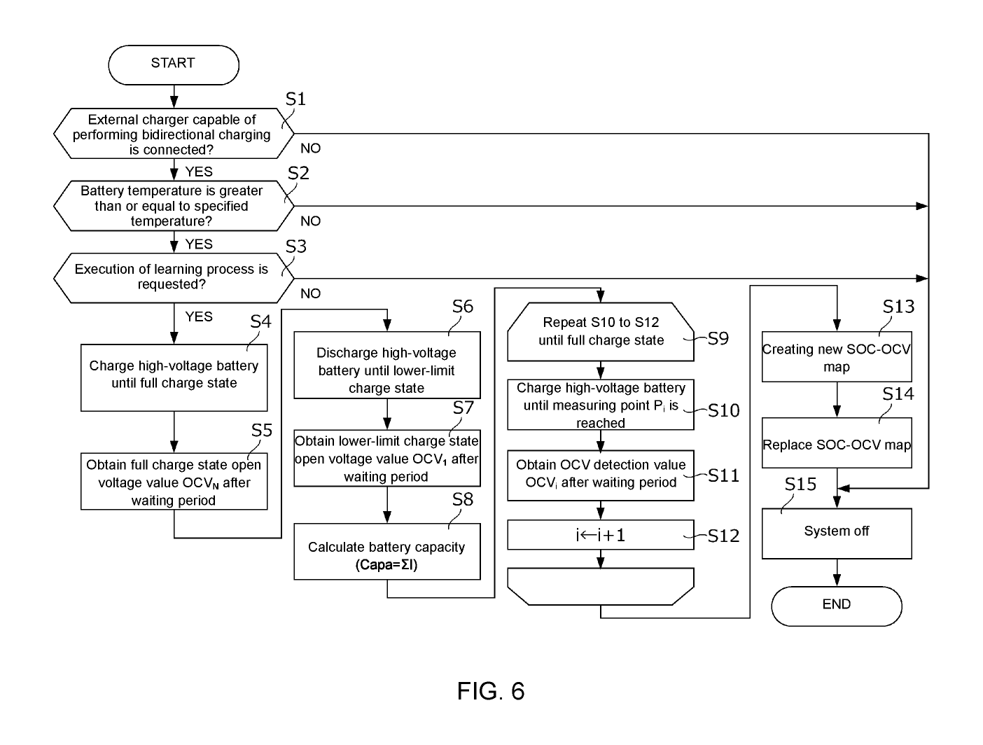

FIG. 6 is a flowchart illustrating the specific procedure of the learning process which learns the correlation characteristic between the SOC and the OCV of the high-voltage battery 2 in the charging ECU 56 and the battery ECU 60. The flowchart of FIG. 6 starts according to the charging ECU 56 and the battery ECU 60 is activated when the user opens the charge lid 52 and inserts the connector 91 into the inlet 51.

Firstly, in S1, the charging ECU 56 determines whether the external charger capable of performing bidirectional charging (that is, both the external charging and the external power supply of the high-voltage battery 2) is connected or not. If the determination result of S1 is YES, the procedure advances to S2, and if the determination result of S1 is NO, the procedure advances to S15.

In S2, the charging ECU 56 obtains a current temperature of the high-voltage battery 2 by using the battery temperature sensor 63, and determines whether the battery temperature is greater than or equal to a specified temperature (0° C., for example) or not. If the determination result of S2 is YES, it is determined that the temperature of the high-voltage battery 2 is suitable for executing the learning process described later, and the procedure advances to S3. If the determination result of S2 is NO, it is determined that the temperature of the high-voltage battery 2 is not suitable for executing the learning process, and the procedure advances to S15. It is not suitable for executing the learning process when the temperature of the high-voltage battery 2 is excessively low since the performance of the high-voltage battery 2 declines.

In S3, the charging ECU 56 determines whether the execution of the learning process is requested by the learning execution determination part 671 or not. As described above, the learning execution determination part 671 requests the execution of the learning process in the case where a predetermined use period has passed from the time started using the high-voltage battery 2 or the previous execution of the learning process, and the user has performed the operation to request the learning process as well. If the determination result of S3 is YES, the procedure advances to S4 and a series of the learning process is started. If the determination result of S3 is NO, the procedure advances to S15.

In S4, firstly, the charging ECU 56 executes the first charging process, and the procedure advances to S5. More specifically, the charging ECU 56 causes the on-vehicle charger 55 to invoke the external charging function so that electric power of the external power source 95 is supplied to the high-voltage battery 2 to charge the high-voltage battery 2 until the battery voltage detected by the battery voltage sensor 62 reaches the upper-limit voltage, that is, until the high-voltage battery 2 turns into the full charge state. When the high-voltage battery 2 turns into the full charge state, the charging ECU 56 stops the on-vehicle charger 55 so as to stop the charging and discharging of the high-voltage battery 2.

In S5, the open-end voltage obtaining part 673 of the battery ECU 60 obtains the full charge state open voltage value OCV_{N} by reading the detection value of the battery voltage sensor 62 after maintaining the state in which no current flows through the high-voltage battery 2 for the predetermined waiting period (a few minutes, for example) after the high-voltage battery 2 has turned into the full charge state and the charging and the discharging have been stopped.

In S6, the charging ECU 56 executes the discharging process, and the procedure advances to S7. More specifically, the charging ECU 56 causes the on-vehicle charger 55 to invoke the external power supply function so that electric power is supplied from the high-voltage battery 2 to the electric load 96 to discharge the high-voltage battery 2 until the battery voltage detected by the battery voltage sensor 62 reaches the lower limit voltage, that is, until the high-voltage battery 2 turns into the lower-limit charge state. When the high-voltage battery 2 turns into the lower-limit charge state, the charging ECU stops the on-vehicle charger 55 so as to stop the charging and the discharging of the high-voltage battery 2. While the charging ECU 56 is performing the discharging process, the battery capacity calculation part 672 of the battery ECU 60 reads the detection value of the battery current sensor 61 at a predetermined cycle and calculates the accumulated value thereof.

In S7, the open-end voltage obtaining part 673 of the battery ECU 60 obtains the lower-limit charge open voltage value OCV₁ by reading the detection value of the battery voltage sensor 62 after maintaining the state in which no current flow through the high-voltage battery 2 for the waiting period after the high-voltage battery 2 enters the lower-limit charge state and stops the charging and the discharging.

In S8, the battery capacity calculation part 672 of the battery ECU 60 calculates the accumulated value of the detection values I of the battery current sensor 61 obtained while the battery turns from the full charge state into the lower-limit charge state in the discharging process, and sets the accumulated value as a battery capacity value Capa.

Next, in S9, the charging ECU 56 and the battery ECU 60 repeats the processes of S10 to S12 until the high-voltage battery 2 turns from the lower-limit charge state into the full charge state, in other words, until the value of a counter i described later (an integer from 2 to N) reaches N, which is the number of the measuring points. Here, whether the high-voltage battery 2 has turned into the full charge state or not may be determined by determining whether the battery voltage has reached the upper-limit voltage or not, as the same as S4, for example, or by determining whether the accumulated value of the detection values of the battery sensor 62 during the charging has reached the battery capacity value Capa calculated in S8 or not.

In S10, the charging ECU 56 performs the intermittent charging process, and moves to S11. More specifically, the charging ECU 56 defines N measuring points P to P_{N} from the lower-limit charge state to the full charge state based on the battery capacity value Capa calculated in S9, and causes the on-vehicle charger 55 to invoke the external charging function so that electric power of the external power source 95 is supplied to the high-voltage battery 2 to charge the high-voltage battery 2 until the high-voltage battery 2 reaches the measuring points Pi specified by the counter i (here, the counter i is an integer with an initial value of 2 and incremented by 1 in S12 described later), that is, until the high-voltage battery 2 enters the full charge state. When the high-voltage battery 2 reaches the measuring point Pi, the charging ECU 56 stops the on-vehicle charger 55 so as to stop the charging and the discharging of the high-voltage battery 2 for the waiting period. Here, whether the high-voltage battery 2 has reached the measuring point Pi or not may be determined by determining whether the accumulated value of the detection values of the battery current sensor 61 has reached the charge amount (Capa/N−1)×i or not.

In S11, the open-end voltage obtaining part 673 of the battery ECU 60 obtains the OCV detected value OCVᵢ at the measuring point Pᵢ by reading the detection value of the battery voltage sensor 62 after maintaining the state in which no current flows through the high-voltage battery 2 for the waiting period after the high-voltage battery 2 reaches the measuring point Pi and stops the charging and the discharging. In S12, the charging ECU 56 adds 1 to the counter i, returns back to S10, and resumes the charging toward the next measuring point Pᵢ+1. As described above, in the processes of S9 to S12, the OCV detection values OCV₂ to OCV_{N-1} at each of the measuring points P₂ to P_{N-1} are obtained by the open-end voltage obtaining part 673 while the charging ECU 56 is performing the intermittent charging process. It is not necessary to proactively obtain the OCV detection values OCV₁ and OCV_{N} in S9 to S12 since these are obtained in S7 and S5 performed earlier.

In S13, the correlation characteristic obtaining part 674 of the battery ECU 60 creates a new SOC-OCV map by generating a curved line passing through N measuring points specified by the SOC threshold values SOC₁ to SOC_{N} and the OCV detection values OCV₁ to OCV_{N} obtained in the previous process by using a known interpolation algorism. The procedure then advances to S14.

In S14, the correlation characteristic obtaining part 674 replaces the current SOC-OVC map defined in the SOC estimation part 66 with the SOC-OCV map newly created in S13 this time. The procedure then advances to S15.

In S15, the charging system S is turned off and the process in FIG. 6 is terminated. The learning process described above requires a few hours from the start in S4 to the completion in S14. Therefore, it may occur that the connector 91 is detached by the user and the vehicle V is activated. In such a case, in one embodiment, the learning process in progress is halted and the old SOC-OCV map is continuously used.

According to the battery state estimation method of the embodiment has following effects:

(1) In the battery state estimation method, firstly, the high-voltage battery 2 is charged until the full charge state is reached (the first charging step in S4), then the high-voltage battery 2 is discharged from the full charge state until the lower-limit charge state, and the battery capacity estimation value of the high-voltage battery 2 is calculated by accumulating the discharge current during the discharging (the discharged step in S6). Here, in the battery state estimation method, although it takes time, the battery capacity of the high-voltage battery 2 can be precisely estimated by using the accumulated value of the discharge current from the full charge state to the lower-limit charge state. Then, in the battery state estimation method, the high-voltage battery 2 is again charged from the lower-limit charge state to the full charge state, and multiple measuring points P₁ to P_{N} are defined between the lower-limit charge state and the full charge state. The charging is halted for the predetermined waiting period every time one of the measuring points is reached during the charging. The OCV of the high-voltage battery 2 is measured after the waiting period has passed, and then the charging is resumed (the second charging step of S9 to S12). Here, in the battery state estimation method, the OCV at each of the measuring points P₁ to P_{N} can be precisely measured by halting the charging for the waiting period every time one of the measuring points P₁ to P_{N} is reached, although it takes time in accordance with the procedure. Also, in the battery state estimation method, since the battery capacity can be precisely estimated by performing the discharging step in advance as described above, the measuring points P₁ to P_{N} can be defined based on the battery capacity, and thereby the SOC at each of the measuring points P₁ to P_{N} can be precisely estimated. In the battery state estimation method, the SOC-OCV map of the high-voltage battery 2 is newly created based on the SOC threshold values SOC₁ to SOC_{N} and the OCV detection values OCV₁ to OCV_{N} at each of the measuring points P₁ to P_{N} obtained as described above. As described above, in the battery state estimation method, although it takes time, it is possible to precisely create the SOC-OCV map, which changes due to degradation, by charging the high-voltage battery 2 until the full charge state once, then discharging the high-voltage battery 2 until the lower-limit state, and then recharging the high-voltage battery 2 until the full charge state. Also, the SOC of the high-voltage battery 2 can be precisely estimated by using such an accurate SOC-OCV map. In addition, in the battery state estimation method, the creation of the SOC-OCV map can be finished in a state that the high-voltage battery 2 is in the full charge state, which is convenient.

(2) In the battery state estimation method, in order to newly create the SOC-OCV map, it requires performing changing, discharging and recharging, which takes time. Therefore, in the battery state estimation method, the correlation characteristic is obtained by performing the first charging step, the discharging step and the second charging step described above while the vehicle V is not travelling, that is, by utilizing the period of time the user does not use the vehicle V. Thereby, it can prevent the convenience of the user from being impaired.

(3) In the battery state estimation method, charging in the first and second charging steps and discharging in the discharging step are performed by using the bidirectional-type on-vehicle charger 55, which can perform the external charging function and the external power supply function. Thereby, in the discharging step, it is possible to efficiently utilize the electric power discharged from the high-voltage battery 2 from the full charge state to the lower-limit charge state for the power network, the electric loads and the like connected to the on-vehicle charger 55.

(4) It is not necessary to frequently update the correlation characteristic of the high-voltage battery 2 since the correlation characteristic gradually changes as degradation of the high-voltage battery 2 progresses. Also, the battery state estimation method takes time because it requires performing discharging and recharging. Therefore, in the battery state estimation method, the learning process is performed to obtain the SOC-OCV map of the high-voltage battery 2 only if the user requests to newly obtain the correlation characteristic via the touch panel P mounted on the vehicle V. Thereby, it can prevent the convenience of the user from being impaired by newly creating the SOC-OCV map on the contrary to the intention of the user.

(5) As mentioned above, it is not necessary to frequently update the correlation characteristic of the high-voltage battery 2 since the correlation characteristic gradually changes as degradation of the high-voltage battery 2 progresses. In the battery state estimation method, the learning process is performed on the condition that at least a predetermined use period has passed from the time started using the high-voltage battery 2 or the time of previous obtainment of the correlation characteristic. Thereby, it can prevent the learning process from being performed more frequently than necessary, thereby preventing the convenience of the user from being impaired.

The present invention is not limited to the embodiment of the present invention described above, and it is possible to properly modify the detailed configuration within the scope of the meaning of the present invention.

For example, in the embodiment described above, the learning execution determination part 671 inquires of the user whether to perform the learning process or not via the touch panel P after a predetermined use period has passed from the time started using the high-voltage battery 2 or the execution time of previous learning process, and requests the execution of the learning process to the charging ECU 56 and the battery capacity calculation part 672 if the operation by which the user requests the execution of learning process is performed. That is, in the embodiment described above, the execution of the learning process is requested when the following two conditions are satisfied: the use period has passed from the time started using the high-voltage battery 2 or the execution time of previous learning process (the first condition) and the operation by which the user requests the execution of learning process is performed (the second condition). However, the present invention is not limited thereto. For example, the learning execution determination part may request the execution of the learning process when either one of the above-mentioned two conditions is satisfied. That is, the learning execution determination part may request the execution of the learning process regardless of the intention of the user after the use period has passed from the time started using the high-voltage battery 2 or the execution time of previous learning process. The learning execution determination part may request the execution of the learning process if the operation by which the user requests the execution of learning process is performed at an arbitrary timing, even the use period has not passed from the time started using the high-voltage battery 2 or the execution time of previous learning process.

Also, in the embodiment described above, for example, the case where the present invention is applied to the vehicle V on which the on-vehicle charger 55 performing the external charging function and the external power supply function is mounted is described. However, the present invention is not limited thereto. The battery state estimation method and the battery state estimation device according to the present invention can be applied to a vehicle mounting an on-vehicle charger that does not have the external power supply function but the external charging function. In the case where the present invention is applied to such a vehicle, in one embodiment, the discharging process in S6 forcibly discharges from the high-voltage battery 2 to the on-vehicle load mounted on the vehicle (specifically, the travel motor M, an auxiliary machinery load 3, a discharge resistor and the like) until the battery voltage detected by the battery voltage sensor 62 reaches the lower-limit voltage, that is, until the high-voltage battery 2 turns into the lower-limit charge state.

What is claimed is:

1. A battery state estimation method that obtains a correlation characteristic between an open-end voltage and a charge rate of a battery that changes due to degradation, comprising
a first charging step for connecting a power source to the battery and charging the battery until a full charge state is reached,
a discharging step for discharging the battery from the full charge state to a lower-limit charge state and calculating a battery capacity of the battery by accumulating a discharge current during the discharging,
a second charging step for recharging the battery from the lower-limit charge state to the full charge state, halting charging for a predetermined period every time one of a plurality of measuring points defined between the lower-limit charge state and the full charge state is reached, measuring the open-end voltage of the battery after the predetermined period has passed, and then resuming charging after the measuring is completed, and
a correlation characteristic obtaining step for obtaining the correlation characteristic of the battery based on the charge rate at each of the measuring points and the open-end voltage measured at each of the measuring points.

2. The battery state estimation method according to claim 1, wherein
the battery is mounted on a movable body, and
the power source is an external power source disposed outside the movable body, and
the first charging step, the discharging step, the second charging step and the correlation characteristic obtaining step are performed upon connection of the external power source is established while the movable body is stopped.

3. The battery state estimation method according to claim 2, wherein
the movable body comprises a bidirectional charger that is capable of performing external charging that charges the battery with electric power supplied by the external power source and external power supply that discharges from the battery to an external supply target disposed outside the moving body, and
charging in the first charging step and the second charging step and discharging in the discharging step are performed using the bidirectional charger.

4. The battery state estimation method according to claim 2, wherein
an obtainment determination unit that is operable by a user to select whether to newly obtain the correlation characteristic or not is mounted on the movable body, and
the first charging step, the discharging step, the second charging step and the correlation characteristic obtaining step are performed only if obtainment of the correlation characteristic is requested via the obtainment determination unit.

5. The battery state estimation method according to claim 1, wherein
the first charging step, the discharging step, the second charging step and the correlation characteristic obtaining step are performed on a condition that at least a predetermined use period has passed from a time started using the battery or a time of previous obtainment of the correlation characteristic.

6. A battery state estimation device that obtains a correlation characteristic between an open-end voltage and a charge rate that changes due to degradation, comprising
a voltage detection unit that detects a voltage of the battery;
a current detection unit that detects a current of the battery;
a charging and discharging unit that supplies electric power from a power source to the battery, and supplies electric power from the battery to a discharge target after the battery is charged until a full charge state is reached so as to discharge the battery until a lower-limit charge state is reached;
a battery capacity calculation unit that calculates a battery capacity of the battery by accumulating a discharge current detected by the current detection unit while the battery is turned from the full charge state into the lower-limit charge state by the charging and discharging unit;
an intermittent charging unit that supplies electric power from the power source to the battery and charges the battery until the full charge state is reached from the lower-limit charge state, and resumes charging after temporarily halting charging for a predetermined period every time one of a plurality of measuring points defined between the lower-limit charge state and the full charge state;
an open-end voltage obtaining unit that obtains an open-end voltage of the battery by the voltage detection unit while the charging is temporarily halted at each of the measuring points by the intermittent charging unit; and
a correlation characteristic obtaining unit that obtains the correlation characteristic of the battery based on the charge rate at each of the measuring points and the open-end voltage measured at each of the measuring points by the open-end voltage obtaining unit.

7. The battery state estimation method according to claim 3, wherein
an obtainment determination unit that is operable by a user to select whether to newly obtain the correlation characteristic or not is mounted on the movable body, and
the first charging step, the discharging step, the second charging step and the correlation characteristic obtaining step are performed only if obtainment of the correlation characteristic is requested via the obtainment determination unit.

8. The battery state estimation method according to claim 2, wherein
the first charging step, the discharging step, the second charging step and the correlation characteristic obtaining step are performed on a condition that at least a predetermined use period has passed from a time started using the battery or a time of previous obtainment of the correlation characteristic.

9. The battery state estimation method according to claim 3, wherein
the first charging step, the discharging step, the second charging step and the correlation characteristic obtaining step are performed on a condition that at least a predetermined use period has passed from a time started using the battery or a time of previous obtainment of the correlation characteristic.

10. The battery state estimation method according to claim 4, wherein
the first charging step, the discharging step, the second charging step and the correlation characteristic obtaining step are performed on a condition that at least a predetermined use period has passed from a time started using the battery or a time of previous obtainment of the correlation characteristic.

11. The battery state estimation method according to claim 7, wherein
the first charging step, the discharging step, the second charging step and the correlation characteristic obtaining step are performed on a condition that at least a predetermined use period has passed from a time started using the battery or a time of previous obtainment of the correlation characteristic.

12. The battery state estimation device according to claim 6, wherein
the battery is mounted on a movable body, and
the power source is an external power source disposed outside the movable body, and
the charging and discharging of the battery performed by the charging and discharging unit, the charging of the battery performed by the intermittent charging u and the obtainment of the correlation characteristic performed by the correlation characteristic obtaining unit are performed upon connection of the external power source is established while the movable body is stopped.

13. The battery state estimation device according to claim 12, wherein
the movable body comprises a bidirectional charger that is capable of performing external charging that charges the battery with electric power supplied by the external power source and external power supply that discharges from the battery to an external supply target disposed outside the moving body, and
the charging and discharging of the battery performed by the charging and discharging unit, and the charging of the battery performed by the intermittent charging unit are performed using the bidirectional charger.

14. The battery state estimation device according to claim 12, further comprising:
an obtainment determination unit that is operable by a user to select whether to newly obtain the correlation characteristic or not is mounted on the movable body, and
the charging and discharging of the battery performed by the charging and discharging unit, the charging of the battery performed by the intermittent charging unit, and the obtainment of the correlation characteristic performed by the correlation characteristic obtaining unit are performed only if the obtainment of the correlation characteristic is requested via the obtainment determination unit.

15. The battery state estimation device according to claim 6, wherein
the charging and discharging of the battery performed by the charging and discharging unit, the charging of the battery performed by the intermittent charging unit, and the obtainment of the correlation characteristic performed by the correlation characteristic obtaining unit are performed on a condition that at least a predetermined use period has passed from a time started using the battery or a time of previous obtainment of the correlation characteristic.

16. A battery state estimation device that obtains a correlation characteristic between an open-end voltage and a charge rate that changes due to degradation, comprising
a voltage detection unit that detects a voltage of the battery;
a current detection unit that detects a current of the battery;
an intermittent charging unit that supplies electric power from a power source to the battery and charges the battery until a full charge state is reached from a lower-limit charge state, and resumes charging after temporarily halting charging for a predetermined period every time one of a plurality of measuring points defined between the lower-limit charge state and the full charge state;
an open-end voltage obtaining unit that obtains an open-end voltage of the battery by the voltage detection unit while the charging is temporarily halted at each of the measuring points by the intermittent charging unit; and
a correlation characteristic obtaining unit that obtains the correlation characteristic of the battery based on the charge rate at each of the measuring points and the open-end voltage measured at each of the measuring points by the open-end voltage obtaining unit.

17. The battery state estimation device according to claim 16, wherein
the battery is mounted on a movable body, and
the power source is an external power source disposed outside the movable body, and
the charging of the battery performed by the intermittent charging unit, and the obtainment of the correlation characteristic performed by the correlation characteristic obtaining unit are performed upon connection of the external power source is established while the movable body is stopped.

18. The battery state estimation device according to claim 17, further comprising:
an obtainment determination unit that is operable by a user to select whether to newly obtain the correlation characteristic or not is mounted on the movable body, and
the charging of the battery performed by the intermittent charging unit, and the obtainment of the correlation characteristic performed by the correlation characteristic obtaining unit are performed only if the obtainment of the correlation characteristic is requested via the obtainment determination unit.

19. The battery state estimation device according to claim 16, wherein
the charging of the battery performed by the intermittent charging unit, and the obtainment of the correlation characteristic performed by the correlation characteristic obtaining unit are performed on a condition that at least a predetermined use period has passed from a time started using the battery or a time of previous obtainment of the correlation characteristic.
